(19) United States
(12) Patent Application Publication
(10) Pub. No.: US 2024/0266236 A1
(43) Pub. Date: Aug. 8, 2024

(54) ELECTRONIC PACKAGE MODULE AND METHOD FOR FABRICATION OF THE SAME

(71) Applicant: USI Science and Technology (Shenzhen) Co., Ltd., Guangdong Province (CN)

(72) Inventors: LI-CHENG SHEN, Guangdong Province (CN); Chao-Hsuan Wang, Guangdong Province (CN)

(21) Appl. No.: 18/355,400

(22) Filed: Jul. 19, 2023

(30) Foreign Application Priority Data
Feb. 8, 2023 (CN) 202310130330.1

(51) Int. Cl. H01L 23/16; H01L 21/56; H01L 23/31; H01L 23/495; H01L 23/538; H01L 25/10

(52) U.S. Cl. CPC H01L 23/16; H01L 21/561; H01L 23/3121; H01L 23/4952; H01L 23/5385; H01L 25/105

(57) ABSTRACT

An electronic package module and the method for fabrication of the same are provided. The method for fabricating the electronic package module includes providing a circuit substrate. An interposer frame and a first electronic component are disposed on the circuit substrate, and a shielding material with an opening overlapping the electronic component is disposed on the interposer frame. Subsequently, with the shielding material being as a mask, the molding material is filled into through the opening, thereby forming the molding layer encapsulating the electronic component. After forming the molding layer, the shielding material is removed, so that an interface of the interposer frame is exposed. Therefore, the solder ball can be disposed on the interface of the interposer frame without further machining of the molding layer.

### RELATED APPLICATIONS

This application claims priority to China Application Serial Number 20/231,0130330.1, filed Feb. 8, 2023, which is herein incorporated by reference in its entirety.

### BACKGROUND

### Technical Field

The present disclosure relates to an electronic package module. More particular, the present disclosure relates to the electronic package module with selective molding and the method for fabrication of the same.

### Description of Related Art

Double sided surface mount technology (SMT) is to mount electronic components on two opposite surfaces of a circuit substrate, and to electronically connect the circuit substrate with a main board through a frame board. The electronic components are mounted on the circuit substrate, and thus, a double sided package structure is formed. Typical transfer molding or compression molding will encapsulate the entire frame board, and thus the molded frame board should be treated by grinding, laser ablation and pre-solder during the process of the connection between the frame board and the main board. Thus, the solder joints on the frame board will be exposed and will electrically connect the frame board with the main board.

However, the processes for solder joints to be exposed are complicated. Furthermore, if the openings formed by laser ablation were deviated from the solders, the yield of the soldering would reduce.

### SUMMARY

Accordingly, the disclosure is to provide an electronic package module and the method for fabrication of the same, thereby improving the reliability.

At least one embodiment of the disclosure provides a method for fabricating an electronic package module, including providing a circuit substrate; disposing an interposer frame and a first electronic component on the circuit substrate; disposing a shielding material on the interposer frame and the shielding material has at least one opening overlapping the first electronic component; using the shielding material as a mask and filling a molding material through the opening, and thus a molding layer encapsulating the first electronic component is formed; and removing the shielding material to expose an interface of the interposer frame after the molding layer is formed.

At least one embodiment of the disclosure provides an electronic package module. The electronic package module includes a circuit substrate, a first electronic component disposed on the circuit substrate and an interposer frame disposed on the circuit substrate and electrically connected to the circuit substrate. The interposer frame includes an interface far away from the circuit substrate. And the electronic package module includes a molding layer encapsulating the first electronic component but exposing the interface. One side of the molding layer far away from the circuit substrate is not flush with the interface.

According to the aforementioned embodiments, the selective molding is conducted in the disclosure with the shielding material covering on the interposer frame, and thus the solder joints on the interposer substrate are exposed without covering by the molding layer. Therefore, the processes of grinding, laser ablation and pre-solder may be omitted, thereby simplifying the fabrication process and improving the reliability.

### BRIEF DESCRIPTION OF THE DRAWINGS

To illustrate more clearly the aforementioned and the other features, merits, and embodiments of the present disclosure, the description of the accompanying figures are as follows:

FIG. 1A to FIG. 1E illustrate cross-sectional views of a method for fabricating an electronic package module in accordance with one embodiment of the present disclosure.

FIG. 2 illustrates a top view of a shielding material in accordance with one embodiment of the present disclosure.

FIG. 3A to FIG. 3B illustrate a cross-sectional views of a method for vacuum printing in accordance with one embodiment of the present disclosure.

FIG. 4 illustrates a cross-sectional view of a method for fabricating an electronic package module in accordance with another embodiment of the present disclosure.

FIG. 5 illustrates a cross-sectional view of an electronic package in accordance with another embodiment of the present disclosure.

FIG. 6A to FIG. 6C illustrate cross-sectional views of a method for fabricating an electronic package module in accordance with another embodiment of the present disclosure.

FIG. 7 illustrates a cross-sectional view of an electronic package in accordance with another embodiment of the present disclosure.

### DETAILED DESCRIPTION

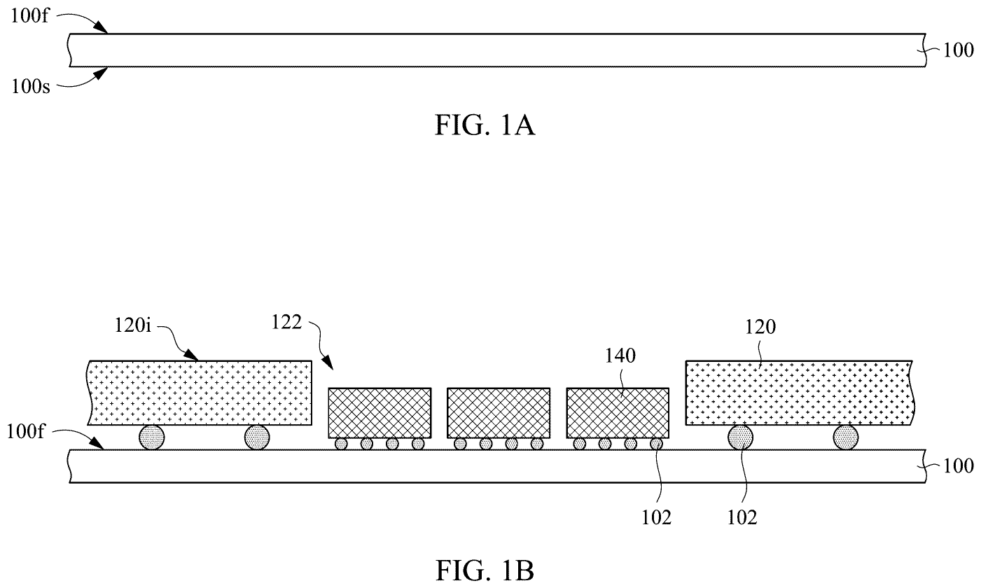

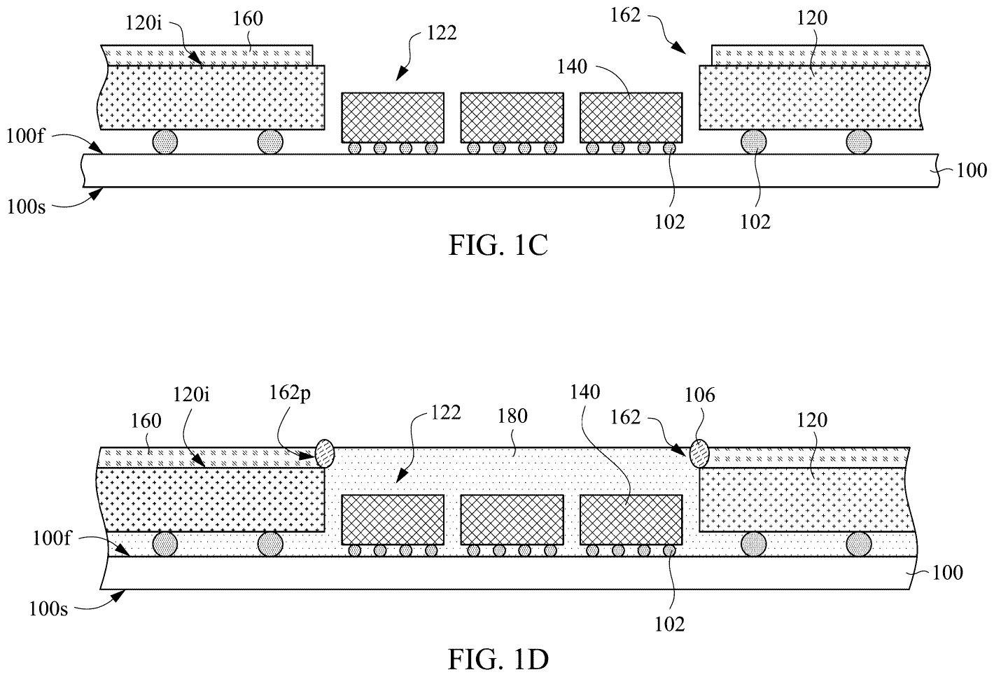

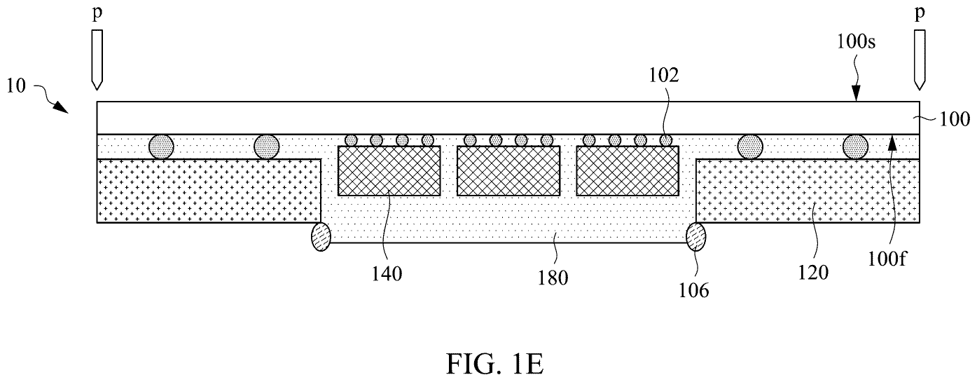

A method for fabrication of the electronic package module is disclosed while FIG. 1A to FIG. 1E illustrate sequent steps of this method in accordance with at least one embodiment of present disclosure. Referring to FIG. 1A, firstly, the circuit substrate 100 including the surface 100f and the surface 100s as its two opposite surfaces is provided. Afterwards, the interposer frame 120 and at least one electronic component 140 are disposed on the surface 100f of the circuit substrate 100 as shown in FIG. 1B. Although the figures of this embodiment depicts three electronic components 140, the number of the electronic components 140 is not limited to three but one and above (such as one or two) in the present disclosure.

In some embodiments, the circuit substrate 100 may further include at least one solder mask (not shown), and the solder mask can cover the surface 100f of the circuit substrate 100 while a plurality of pads (not shown) are exposed on the surface 100f. The electronic components 140 are soldered and mounted on the circuit substrate 100 by a plurality of solders 102 via these pads, so that the electronic components 140 are electrically connected to the circuit substrate 100. The solders 102 may be solder balls, copper pillars or other connecting structures for electrical connection. Furthermore, the electronic components 140 may be electrically connected to the circuit substrate 100 with wire-bonding in other embodiments. The electronic components 140 may be packaged as a chip or unpackaged as a die.

Referring to FIG. 1B, the interposer frame 120 includes the interface 120i which is far away from the circuit substrate 100, that is, the interface 120i backs to the surface 100f of the circuit substrate 100. In this embodiment, the number of the interposer frame 120 is one, and the interposer frame 120 includes at least one opening 122 where the electronic components 140 are disposed. However, the number of the interposer frame 120 may be one and above, and each of the interposer frame 120 may include one and above opening 122 (for example, one opening 122) in other embodiments. In this embodiment, the opening 122 included in the interposer frame 120 is in the shape of a closed ring, that is, the perimeter of the opening 122 is surrounded by the interposer frame 120. However, the disclosure is not limited to this embodiment. In other embodiments, the opening 122 may be a gap between two interposer frames 120 which are juxtaposed on the circuit substrate 100, and thus the opening 122 may be a non-closed strip.

In the same way of the electronic components 140 being connected to the circuit substrate 100, the interposer frame 120 is electrically connected to the circuit substrate 100 by the plurality of solders 102 via the pads (not shown) which are exposed on the circuit substrate 100. It is worth mentioning, although the interface 120i of the interposer frame 120 is above the top side of the electronic components 140, the disclosure is not limited by this embodiment. In other embodiments, the interface 120i of the interposer frame 120 may be below or flush with the top side of the electronic components 140.

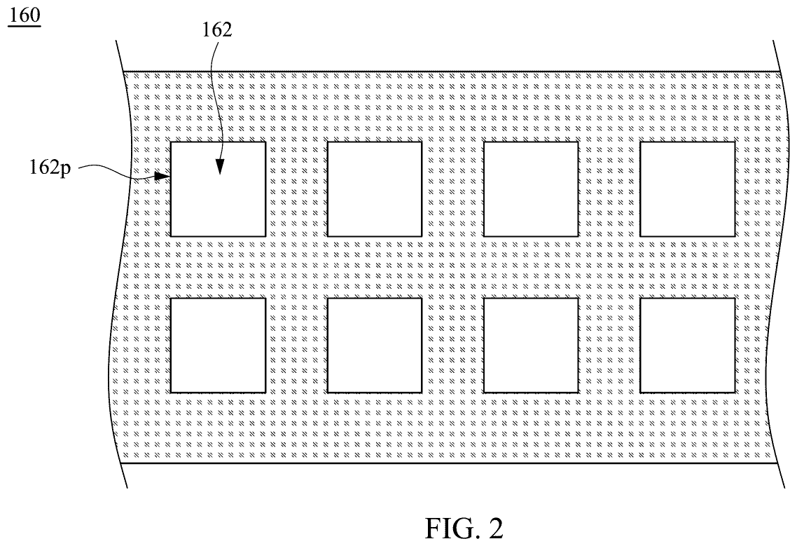

Referring to FIG. 1C, the shielding material 160 is disposed on the interposer frame 120 after the interposer frame 120 and the electronic components 140 are disposed on the circuit substrate 100. FIG. 2 illustrates the shielding material 160 partially. Referring to FIG. 1C and FIG. 2, the shielding material 160 has at least one opening 162 which overlaps the electronic components 140, so that the electronic components 140 are not covered by the shielding material 160. The shielding material 160 may be a steel stencil or other alloy stencil, but the shielding material 160 is not limited to be a metal stencil. For example, the shielding material 160 may be a ceramic plate or a tape including polymers (such as polyimide tape).

The shielding material 160 may include the plurality of openings 162 as shown in FIG. 2. Since these openings 162 should overlap the electronic components 140 while the electronic components 140 are disposed in the openings 122 of the interposer frame 120, the numbers and the positions of the openings 162 are in accordance with the openings 122 of the interposer frame 120. In addition, the disclosure is not limited to this embodiment that the shielding material 160 covers the interposer frame 120 partially. In other embodiments, the shielding material 160 may cover the entire interposer frame 120. In other words, the size and the shape of the openings 122 of the interposer frame 120 may be different from the size and the shape of the openings 162 of the shielding material 160.

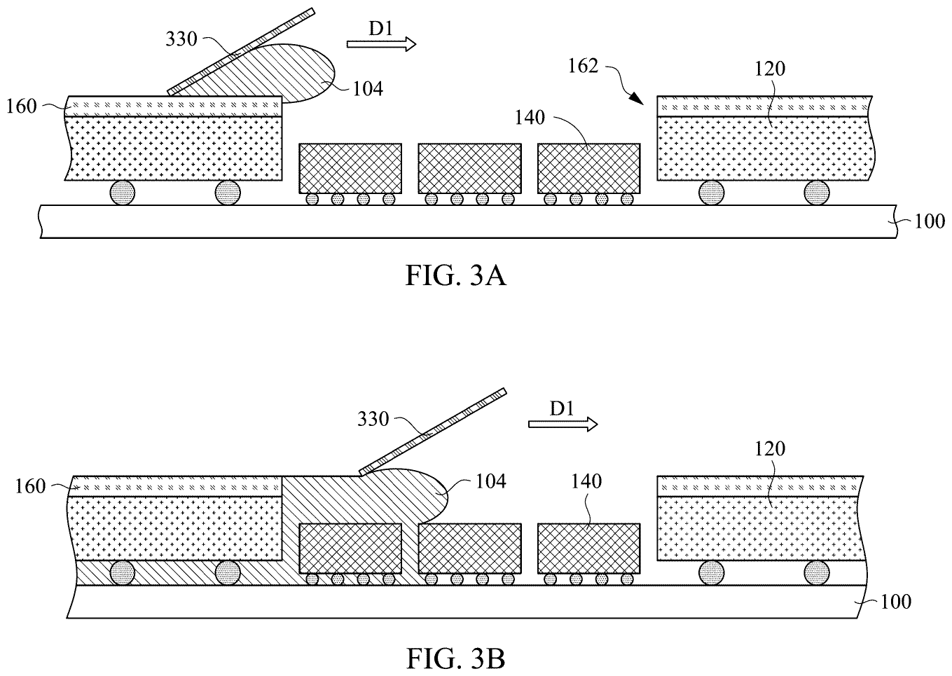

Afterwards, referring to FIG. 1D, the shielding material 160 is used as a mask and the molding material 104 (denoted in FIG. 3A and FIG. 3B) is filled into through the opening 162, so that the molding layer 180 is formed. The molding layer 180 encapsulates the electronic components 140. In this embodiment, the molding layer 180 encapsulates the entire electronic components 140 except for the contacted regions between the solders 102 and the electronic components 140. However, the disclosure is not limited to this embodiment, the molding layer 180 may expose some parts of the electronic components 140.

In addition, the molding layer 180 encapsulates the interposer frame 120 partially. For example, the molding layer 180 encapsulates the bottom surface (not denoted) and the side surface (not denoted) of the interposer frame 120 but does not encapsulate the interface 120i of the interposer frame 120. However, the molding layer 180 may cover the interface 120i of the interposer frame 120 partially in other embodiments. The material of the molding layer 180 may include organic resin (such as epoxy resin) or other isolation material, or similarity thereof.

It is worth mentioning, the molding material 104 in fluid form is filled into by vacuum printing. In particular, referring to FIG. 3A and FIG. 3B, firstly, the molding material 104 to be filled into is disposed on the shielding material 160. Afterwards, a scraper (or a squeegee) 330 is settled on the shielding material 160 with an angle between the scraper 330 and the shielding material 160 while the molding material 104 is disposed within the angle between the scraper 330 and the shielding material 160.

The following step is shown in FIG. 3B. The scraper 330 is forced to move along with the direction D1, and then pushes the molding material 104 to fill into through the opening 162. The direction D1 shown in FIG. 3A and FIG. 3B is horizontal. After the molding material 104 is filled into, the molding material 104 may be cured to form the molding layer 180 by thermal curing (e.g. baking), drying or UV irradiation.

During the process of vacuum printing, the object to be printed is disposed into a sealed chamber, and this sealed chamber remains in vacuum. Under vacuum environment, the molding material 104 may be filled into evenly, hence, less bubbles will be produced. However, the method for filling the molding material 104 is not limited to vacuum printing but other similar molding methods thereof.

Referring to FIG. 1D and FIG. 2, the barrier 106 is disposed on the interposer frame 120 along with the perimeter 162p around the opening 162 of the shielding material 160 before the molding material 104 (denoted in FIG. 3A and FIG. 3B) is filled into. The barrier 106 directly touches the interposer frame 120 and surrounds the entire perimeter 162p, so that a retaining wall structure is formed on the interposer frame 120. The barrier 106 is used as a retaining wall for preventing the molding material 104 from overflowing to the interposer frame 120. As a result, the barrier 106 should be disposed according to the interposer frame 120. The barrier 106 may be in other shape in other embodiments even though the barrier 106 is in the shape of a closed ring in this embodiment. Furthermore, the barrier 106 directly touches the shield material 160 in this embodiment. However, the barrier 106 may be disposed on the interposer frame 120 without a direct touch on the shielding material 160.

The barrier 106 is used for preventing the surplus molding material 104 from overflowing to the joint or the seam between the interposer frame 120 and the shielding material 160, thereby preventing the molding material 104 to contaminate the interface 120i. However, the barrier 106 may not be disposed according to the circumstance of the filling of the molding material 104 in some embodiments. In the embodiment, the barrier 106 may be formed around the perimeter 162p of the opening 162 by such as dispensing. The barrier 106 may include adhesive material such as white paint, white glue, epoxy resin or similarity thereof.

The shielding material 160 is removed and the interface 120i of the interposer frame 120 is exposed after the molding layer 180 is formed. In the embodiment, the barrier 106 does not have to be removed as the shielding material 160 is removed, and thus the barrier 106 may remain on the interposer frame 120. Referring to FIG. 1E, the circuit substrate 100, the molding layer 180 and the interposer frame 120 are cut by such as machine cutting, laser cutting or focus ion beam cutting after the shielding material 160 is removed. As shown in FIG. 1E, the cutting device p cuts the circuit substrate 100 from the surface 100s and along with the normal of the circuit substrate 100, so that the plurality of electronic package elements 10 are formed. The cutting device p in FIG. 1E may represent a cutter, a laser beams or an ion beam. Moreover, in some embodiments, only the circuit substrate 100 and the molding layer 180 may be cut while the interposer frame 120 may not be cut during this step.

It should be noted, although the cutting is performed after the formation of the molding layer 180 in this embodiment, the cutting is not limited to be in this sequence. In other embodiments, the circuit substrate 100, the molding layer 180 and the interposer frame 120 may be cut before the shielding material 160 is disposed.

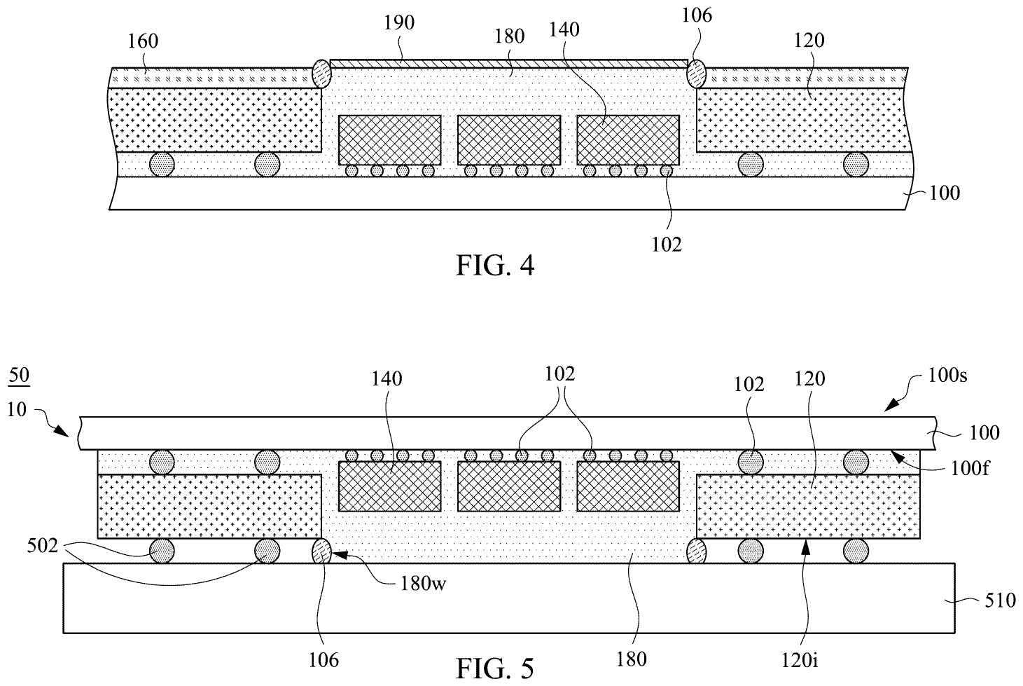

Referring to FIG. 4, in another embodiment, the metal layer 190 may be deposited on the molding layer 180 by sputtering, stencil printing, coating or other similar method. The metal layer 190 overlaps the electronic components 140 without a direct touch on the electronic components 140. In order to efficiently dissipate the heat from the electronic components 140, the metal layer 190 may include materials such as copper, tin or the alloy thereof, and thus prevent the electronic components 140 from overheating.

Referring to FIG. 5, the interposer frame 120 is connected to the main board 510 after the shielding material 160 is removed and the electronic package elements 10 are formed by cutting. The interface 120i of the interposer frame 120 is connected to the main board 510, that is, the surface 100f of the circuit substrate 100 faces to the main board 510. In this step, a plurality of solder materials 502 are disposed on the interface 120i of the interposer frame 120. The material of the solder materials 502 may be the same as the material of the solders 102. Afterwards, the interposer frame 120 is connected to the main board 510 through the solder materials 502 with the method of soldering.

Referring to FIG. 5, the structure of the electronic package module in at least one embodiment is disclosed. The electronic package module 50 of this embodiment includes the circuit substrate 100, the interposer frame 120, the electronic components 140 and the molding layer 180. The electronic components 140 are mounted on the surface 100f of the circuit substrate 100 and are electrically connected to the circuit substrate 100 via the plurality of solders 102.

Although the figure of this embodiment depicts three electronic components 140 apiece, the number of the electronic components 140 is not limited to three but one and above (such as one or two) in the present disclosure. In addition, the interposer frame 120 is on the surface 100f and is electrically connected to the circuit substrate 100 via the plurality of solders 102. The interposer frame 120 includes the interface 120i which is far away from the circuit substrate 100, that is, the interface 120i backs to the surface 100f of the circuit substrate 100.

Referring to FIG. 5, the molding layer 180 encapsulates the electronic components 140. The material of the molding layer 180 may include organic resin (such as epoxy resin) or other isolation material, or similarity thereof. In this embodiment, the molding layer 180 encapsulates the entire electronic components 140 except for the contacted regions between the solders 102 and the electronic components 140 while the interface 120i of the interposer frame 120 is exposed. However, the present disclosure is not limited to the embodiment, the molding layer 180 may cover the interface 120i of the interposer frame 120 partially while the pads (not shown) on the interface 120i are not covered.

The side of the molding layer 180 far away from the circuit substrate 100 is not flush with the interface 120i. Further, the molding layer 180 protrudes from the interface 120i in this embodiment, while the molding layer 180 may indent from the interface 120i in some other embodiments. In the embodiment that the molding layer 180 protrudes from the interface 120i, the molding layer 180 may partially cover interface 120i of the interposer frame 120.

Referring to FIG. 5, the electronic package module 50 further includes the barrier 106 located on the interface 120i of the interposer frame 120. The part of the molding layer 180 protruding from the interface 120i has the side wall 180w, and the barrier 106 surrounds the molding layer 180 along with the side wall 180w. It is worth mentioning, the present disclosure is not limited to the embodiment that the barrier 106 surrounds the entire molding layer 180, and thus is formed in the shape of a closed ring. In other embodiments, the barrier 106 may be formed in other shapes, for example, the barrier 106 may extend along with one side (or two sides) of the molding layer 180, and thus is formed in the shape of a strip. In addition, the present disclosure is not limited to the embodiment that the barrier 106 directly touches the side wall 180w of the molding layer 180. The side wall 180w may be separated from the barrier 106, that is, the side wall 180w may not directly touch the barrier 106 in other embodiments. Furthermore, the electronic package module 50 may exclude the barrier 106 in other embodiments.

The electronic package module 50 further includes the plurality of solder materials 502 located on the interface 120i and includes the main board 510. As shown in FIG. 5, the solder materials 502 directly touch and are electrically connected to the interposer frame 120. In addition, the main board 510 faces to the interface 120i and is connected to the solder materials 502, so that the interposer frame 120 and the electronic components 140 are located between the circuit substrate 100 and the main board 510. In the electronic package module 50, the interposer frame 120 is electrically connected to the main board 510 through these solder materials 502. The material of the solder materials 502 may be the same as the material of the solders 102.

In another embodiment of the present disclosure, a metal layer may be located between the main board 510 and the molding layer 180. For example, the metal layer 190 shown in FIG. 4 overlaps the electronic components 140 and the molding layer 180. The metal layer 190 may be deposited on the molding layer 180 by sputtering, stencil printing, coating or other similar method. In the embodiment, the metal layer 190 may be thermally connected to the main board 510, thereby increasing the rate of heat dissipation from the electronic components 140 to the main board 510. In particular, the main board 510 includes at least one pad (not shown) and may be connected to the metal layer 190 via these pads, so that the metal layer 190 is thermally connected to the main board 510. It is worth mentioning that the pads may be electrically connected to the grounding circuit of the main board 510 in order to ground the metal layer 190.

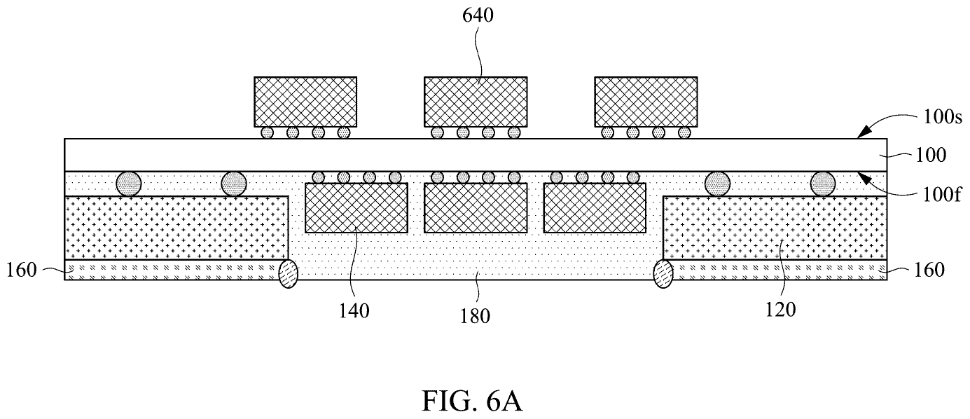

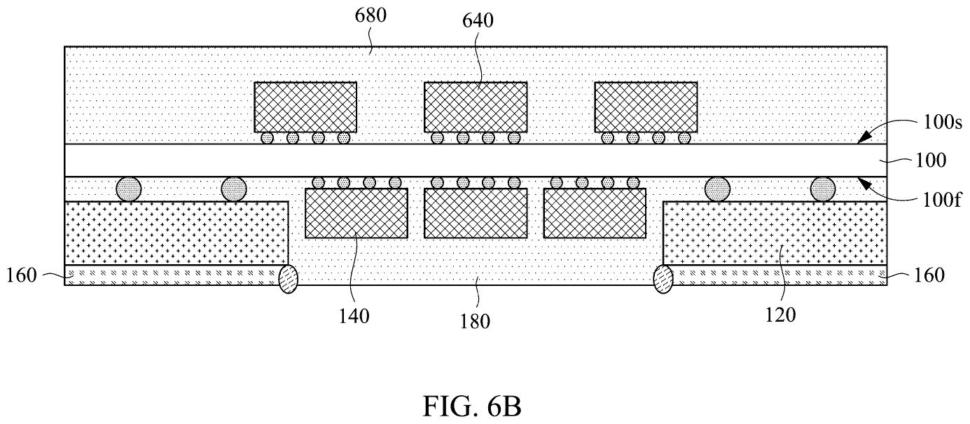

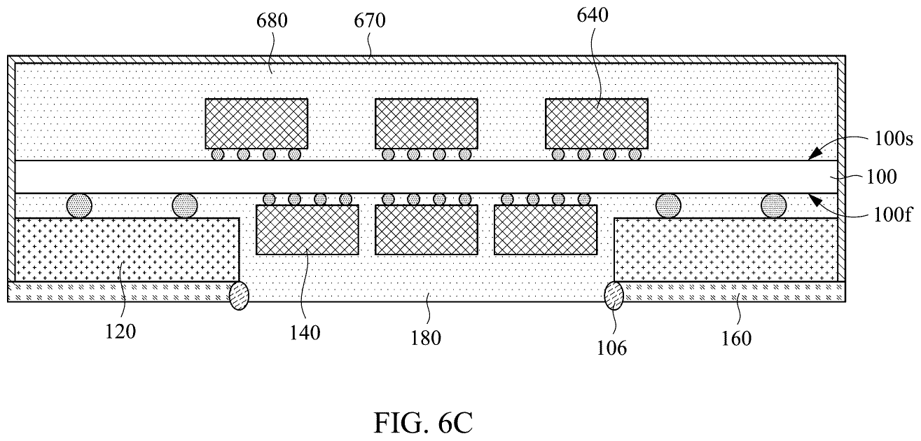

FIG. 6A to FIG. 6C illustrate a cross-sectional view of a method for fabricating an electronic package module in accordance with another embodiment of the present disclosure, and the step of FIG. 6A can follow up the step of FIG. 1D. The steps before FIG. 6A of this embodiment are the same as the FIG. 1A to FIG. 1D, and thus, the descriptions of those steps are not repeated hereof.

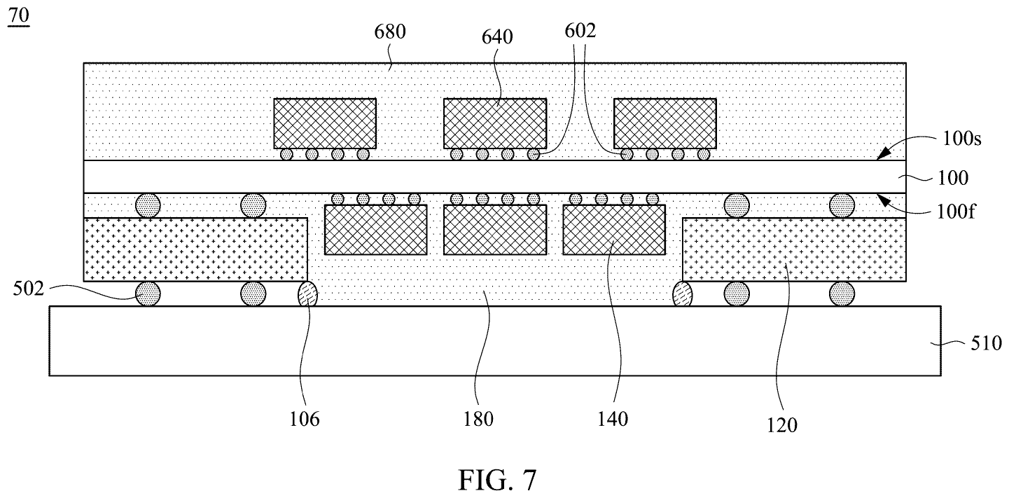

Referring to FIG. 6A, the electronic components 640 are disposed on the other surface 100s of the circuit substrate 100 after the molding layer 180 is formed. Thus, the electronic components 140 and the electronic components 640 are disposed on two opposites of the circuit substrate 100 respectively. The types of the electronic components 640 may be the same as the types of the electronic components 140. The electronic components 640 may be electrically connected to the circuit substrate 100 via both the pads (not shown) exposed on circuit substrate 100 and the plurality of solders 602 (denoted in FIG. 7). The solders 602 may be the same as the solders 102. In other embodiments, the electronic components 640 may be electrically connected to the circuit substrate 100 with wire-bonding. Furthermore, although the figure of this embodiment depicts three electronic components 640 apiece, the number of the electronic components 640 is not limited to three but one and above (such as one) in the present disclosure.

Referring to FIG. 6B, the molding layer 680 is formed on the surface 100s after the electronic components 640 are disposed, so that the molding layer 680 encapsulates the electronic components 640. The material of the molding layer 680 may include organic resin (such as epoxy resin) or other isolation material, or similarity thereof. Moreover, the molding layer 680 may not be formed in other embodiments of the present disclosure. In other words, the step of FIG. 6B may be omitted.

It is worth mentioning, the present disclosure is not limited to this embodiment that the steps shown in FIG. 6A to FIG. 6B are conducted after the step of FIG. 1D. In particular, the steps shown in FIG. 6A to FIG. 6B may be conducted before the step of FIG. 1B in some embodiments. To take FIG. 1A and FIG. 1B for example, the electronic components 640 may be disposed on the surface 100s of the circuit substrate 100 before the electronic components 140 are disposed on the surface 100f of the circuit substrate 100.

The following steps of this embodiment after FIG. 6B are similar to the steps of the aforementioned embodiment illustrated in FIG. 1E. The difference between this embodiment and the aforementioned embodiment is that the electrical conductive layer 670 may be deposited on the molding layer 680 before the shielding material 160 is disposed, as shown in FIG. 6C. Since the electrical conductive layer 670 completely covers the electronic components 640, the electrical conductive layer 670 may electromagnetically shield the electronic components 640. The material of the electrical conductive layer 670 may include metals (such as copper, nickel or alloys), conductive adhesive or other materials and may be deposited with spin coating, sputtering, chemical plating or other similar methods. It should be noted that the cutting process should be conducted before the electrical conductive layer 670 is deposited, so that the electrical conductive layer 670 can cover the side surfaces of the electronic components 640, thereby electromagnetically shielding the electronic components 640 completely.

FIG. 7 illustrates the cross-section view of the electronic package module 70 in accordance with another embodiment of present disclosure. The difference between the electronic package module 70 and the electronic package module 50 is that the electronic package module 70 further includes the electronic components 640 and the molding layer 680. The electronic components 640 are disposed on the other surface 100s of the circuit substrate 100, thus, the electronic components 140 and the electronic components 640 are disposed on two opposites of the circuit substrate 100 respectively. Although the figure of this embodiment depicts three electronic components 640 apiece, the number of the electronic components 640 is not limited to three but one and above (such as one) in the present disclosure. In addition, the electronic components 640 are electrically connected to the circuit substrate 100 via the plurality of solders 602.

In some embodiments, other devices such as antennas may be disposed on the surface 100s instead of the electronic components 640, and the electrical conductive layer 670 in FIG. 6C may be excluded from the electronic package module 70. In this embodiment, the molding layer 680 encapsulates the electronic components 640, and the molding layer 680 encapsulates the entire electronic components 640. However, in other embodiments, the molding layer 680 may partially or may not encapsulate the electronic components 640. The material of the molding layer 680 may include organic resin (such as epoxy resin) or other isolation material, or similarity thereof. Moreover, the electronic package module 70 may even exclude the molding layer 680 in some embodiments.

In conclusion, since the shielding material covers the interface of the interposer frame, a part of the interface including solder joints is exposed without covering by the molding layer. As a result, the solder materials may be disposed on the exposed solder joints directly when the interposer should be soldered on the main board. Therefore, the processes of grinding, laser ablation and pre-solder may be omitted, thereby simplifying the fabrication process. Furthermore, the deviations which lead to reliability issues from the machining processes can be prevented, and thus the yield of soldered products is improved.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A method for fabricating an electronic package module, comprising:
providing a circuit substrate;
disposing an interposer frame and a first electronic component on the circuit substrate;
disposing a shielding material on the interposer frame and the shielding material has at least one opening overlapping the first electronic component;
using the shielding material as a mask and filling a molding material through the opening, and thus a molding layer is formed, wherein the molding layer encapsulates the first electronic component; and
removing the shielding material to expose an interface of the interposer frame after the molding layer is formed.

2. The method of claim 1, further comprising:
disposing a plurality of solder materials on the interface of the interposer frame; and
connecting the circuit substrate with a main board through the plurality of solder materials after disposing the plurality of solder materials.

3. The method of claim 1, further comprising:
disposing a barrier surrounding a perimeter of the opening on the interposer frame before filling the molding material.

4. The method of claim 1, further comprising:
forming a metal layer on the molding layer, wherein the metal layer overlaps the first electronic component.

5. The method of claim 1, further comprising:
disposing a second electronic component on the circuit substrate, and the second electronic component and the circuit substrate are on two opposites of the circuit substrate respectively.

6. The method of claim 1, further comprising:
cutting the circuit substrate, the molding layer and the interposer frame after removing the shielding material.

7. The method of claim 1, wherein filling into the molding material is by a method of vacuum printing.

8. An electronic package module, comprising:
a circuit substrate;
a first electronic component disposed on the circuit substrate;
an interposer frame disposed on the circuit substrate and electrically connected to the circuit substrate, wherein the interposer frame comprises an interface far away from the circuit substrate; and
a molding layer encapsulating the first electronic component but exposing the interface;
wherein one side of the molding layer far away from the circuit substrate is not flush with the interface.

9. The electronic package module of claim 8, wherein the molding layer protrudes from the interface and partially covers the interface of the interposer frame.

10. The electronic package module of claim 8, further comprising:
a barrier disposed on the interface of the interposer frame, wherein a part of the molding layer protruding from the interface has a side wall, and the barrier is disposed along with the side wall;
wherein the barrier directly touches the side wall.

11. The electronic package module of claim 8, further comprising:
a plurality of solder materials disposed on the interface and electrically connected to the interposer frame; and
a main board connected to the plurality of solder materials, wherein the interposer frame and the first electronic component is disposed between the circuit substrate and the main board.

12. The electronic package module of claim 11, further comprising:
a metal layer disposed between the main board and the molding layer, and overlapping the first electronic component and the molding layer;
wherein the metal layer is thermally connected to the main board.

13. The electronic package module of claim 12, wherein the main board comprising:
a pad connected to the metal layer.

14. The electronic package module of claim 8, further comprising:
a second electronic component disposed on the circuit substrate, wherein the first electronic component and the second electronic component are disposed on two opposites of the circuit substrate respectively.
